(19) United States
(12) Patent Application Publication
(10) Pub. No.: US 2026/0051891 A1
(43) Pub. Date: Feb. 19, 2026

(54) LEVEL SHIFT CIRCUIT

(71) Applicant: EMEMORY TECHNOLOGY INC., HSINCHU (TW)

(72) Inventors: CHIH-YANG HUANG, HSINCHU COUNTY (TW); WEI-MING KU, HSINCHU COUNTY (TW); WEI-CHIANG ONG, HSINCHU COUNTY (TW)

(21) Appl. No.: 19/290,366

(22) Filed: Aug. 5, 2025

Related U.S. Application Data
(60) Provisional application No. 63/682,408, filed on Aug. 13, 2024.

(51) Int. Cl. H03K 19/0185; H03K 3/037; H03K 19/20

(52) U.S. Cl. CPC H03K 19/018507; H03K 3/037; H03K 19/20

(57) ABSTRACT

A level shift circuit includes a first voltage boost unit, a second voltage boost unit, a latch, a first transistor and a second transistor. The first voltage boost unit and the second voltage boost unit boost voltage levels of a first input signal and a second input signal so as to generate a first control signal and a second control signal. The first transistor and the second transistor pull down voltages levels of a first terminal and a second terminal of the latch according to the first control signal and the second control signal to a system voltage respectively. The latch latches a voltage of one of the first terminal and the second terminal of the latch at a high operation voltage and latch a voltage of another terminal of the latch at the system voltage.

### CROSS REFERENCE

This application claims the benefit of prior-filed U.S. provisional application No. 63/682,408, filed on Aug. 13, 2024, which is incorporated by reference in its entirety.

### TECHNICAL FIELD

The present disclosure relates to a level shift circuit, and more particularly, to a latch type level shift circuit.

### DISCUSSION OF THE BACKGROUND

Level shift circuits are commonly used in electronic circuits to ensure that signals are compatible with different components or systems of different power domains. For example, if a signal needs to be transferred from one circuit operating at a certain voltage level to another circuit operating at a different voltage level, a level shift circuit may be adopted to shift the voltage level of the signal so as to ensure proper communication between the circuits.

However, as the level shift circuit needs to operate within a wide voltage range, special cares need to be taken so as to protect the components from being broken down due to cross voltage, while ensuring their functionality.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a level shift circuit. The level shift circuit includes a first voltage boost unit, a second voltage boost unit, a latch, a first transistor, and a second transistor. The first voltage boost unit is configured to generate a first control signal according to a first input signal switched between a first operation voltage and a system voltage lower than the first operation voltage, wherein the first control signal is positively correlated to the first input signal and is at a boost voltage higher than the first operation voltage when the first input signal is at the first operation voltage. The second voltage boost unit is configured to generate a second control signal according to a second input signal switched between the first operation voltage and the system voltage and complementary to the first input signal, wherein the second control signal is positively correlated to the second input signal and is at the boost voltage when the second input signal is at the first operation voltage. The latch includes a first terminal and a second terminal, and is configured to latch a voltage of one of the first terminal and the second terminal of the latch at a second operation voltage higher than the first operation voltage and latch a voltage of another of the first terminal and the second terminal of the latch at the system voltage. The first transistor includes a first terminal coupled to the first terminal of the latch, a second terminal, and a control terminal configured to receive the first control signal. The second transistor includes a first terminal coupled to the second terminal of the latch, a second terminal, and a control terminal configured to receive the second control signal.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a level shift circuit according to a comparative embodiment of the present disclosure.

FIG. 2 shows a level shift circuit according to one embodiment of the present disclosure.

FIG. 3 shows a timing diagram of the level shift circuit in FIG. 2 according to one embodiment of the present disclosure.

FIG. 4 shows a level shift circuit according to another embodiment of the present disclosure.

FIG. 5 shows a level shift circuit according to another embodiment of the present disclosure.

FIG. 6 shows a timing diagram of the input signals and the pulse signals.

FIG. 7 shows a first pulse generator in FIG. 5 according to one embodiment of the present disclosure.

FIG. 8 shows a second pulse generator in FIG. 5 according to one embodiment of the present disclosure.

FIG. 9 shows a level shift circuit according to another embodiment of the present disclosure.

### DETAILED DESCRIPTION

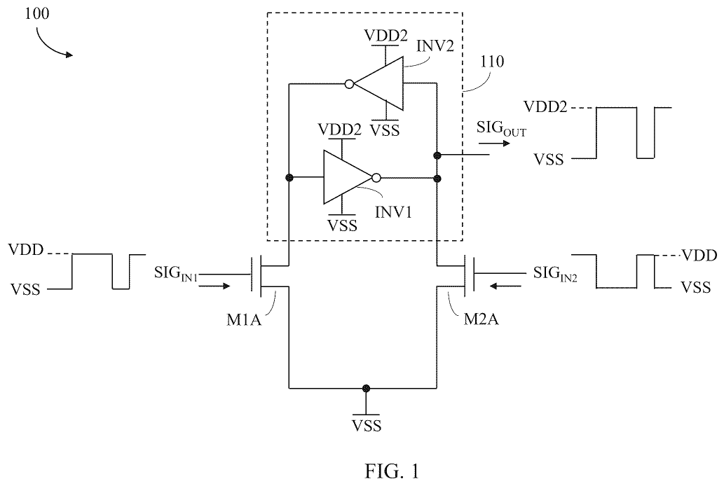

FIG. 1 shows a level shift circuit 100 according to a comparative embodiment of the present disclosure. The level shift circuit 100 receives input signals SIG_{IN1} and SIG_{IN2}, and generates an output signal SIG_{OUT} by adjusting the input signal SIG_{IN1} or SIG_{IN2} to a higher voltage level. Specifically, the input signals SIG_{IN1} and SIG_{IN2} can be complementary to each other and can be switched between a first operation voltage VDD and a system voltage VSS, and the output signal SIG_{OUT} can be switched between a second operation voltage VDD2 and the system voltage VSS, where the second operation voltage VDD2 is higher than the first operation voltage VDD, and the first operation voltage VDD is higher than the system voltage VSS.

The level shift circuit 100 includes a latch 110 and transistors M1A and M2A. The latch 110 includes a first terminal and a second terminal. In the present embodiments, the latch 110 can output its output signal SIG_{OUT} by its second terminal. The latch 110 includes inverters INV1 and INV2 that are cross coupled between the first terminal and the second terminal of the latch 110 and receive the second operation VDD2 as power supply. Specifically, the inverter INV1 includes an input terminal coupled to the first terminal of the latch 110, and an output terminal coupled to the second terminal of the latch 110. The inverter INV2 includes an input terminal coupled to the second terminal of the latch 110, and an output terminal coupled to the first terminal of the latch 110.

The transistor M1A includes a first terminal coupled to the first terminal of the latch 110, a second terminal coupled to the system voltage VSS, and a control terminal for receiving the input signal SIG_{IN1}. The transistor M2A includes a first terminal coupled to the second terminal of the latch 110, a second terminal coupled to the system voltage VSS, and a control terminal for receiving the input signal SIG_{IN2.}

When the input signal SIG_{IN1} is at the first operation voltage VDD and the input signal SIG_{IN2} is at the system voltage VSS, the transistor M1A should be turned on and the transistor M2A should be turned off, thereby pulling down the voltage of the first terminal of the latch 110. Consequently, the voltage of the first terminal of the latch 110 is at the system voltage VSS, and the voltage of the second terminal of the latch 110 is at the second operation voltage VDD2. Likewise, when the input signal SIG_{IN1} is at the system voltage VSS and the input signal SIG_{IN2} is at the first operation voltage VDD, the transistor M2A should be turned on and the transistor M1A should be turned off. As a result, the voltage of the second terminal of the latch 110 is at the system voltage VSS, and the voltage of the first terminal of the latch 110 is at the second operation voltage VDD2.

In some embodiments, the system voltage VSS can be the ground voltage (i.e., 0V), the first operation voltage VDD can be about 1.2V, and the second operation VDD2 can be about 3.3V or 5V or higher. In such case, the transistors M1A and M2A may be high voltage transistors or medium voltage transistors that have thicker gate oxide so as to endure higher cross voltages up to 3.3V or 5V. However, transistors that can endure such high cross voltages may also have higher threshold voltages. Therefore, in some cases, due to the process variations, for example, the transistors M1A and M2A may have threshold voltages slightly lower than or equal to, or in some embodiments even higher, than the first operation voltage VDD, making it difficult to turn on the transistors M1A and M2A with the input signals SIG_{IN1} and SIG_{IN2.}

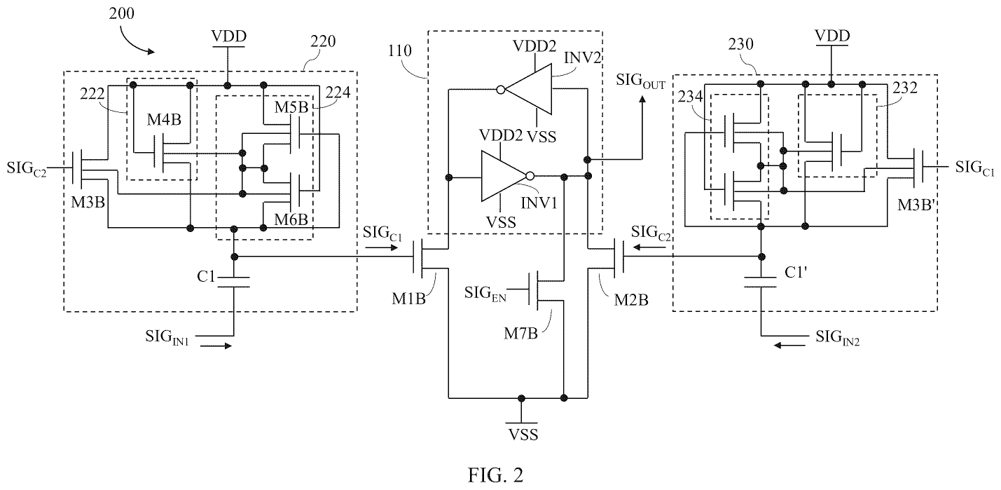

FIG. 2 shows a level shift circuit 200 according to one embodiment of the present disclosure. The level shift circuit 200 is different from the level shift circuit 100 in that the level shift circuit 200 further includes voltage boost units 220 and 230. The voltage boost units 220 and 230 can boost the voltage levels of the input signal SIG_{IN1} and SIG_{IN2} so that the transistor M1B can be turned on accordingly when the input signal SIG_{IN1} is at the first operation voltage VDD, and the transistor M2B can be turned on accordingly when the input signal SIG_{IN2} is at the first operation voltage VDD.

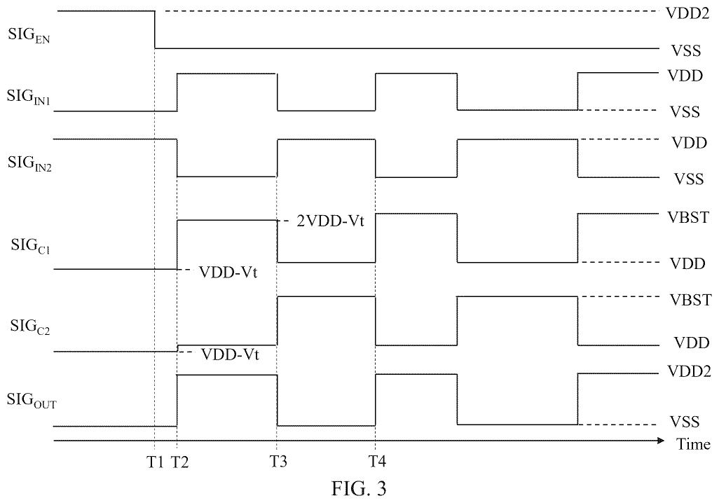

Specifically, the voltage boost unit 220 can generate a control signal SIG_{C1} according to the input signal SIG_{IN1}, and the voltage boost unit 230 can generate a control signal SIG_{C2} according to the input signal SIG_{IN2}. FIG. 3 shows a timing diagram of the level shift circuit 200 according to one embodiment of the present disclosure. As shown in FIG. 3, after the level shift circuit 200 is enabled (e.g., after time T1) and after the level shift circuit 200 is initialized (e.g., after time T3), the control signal SIG_{C1} would be at a boost voltage VBST higher than the first operation voltage VDD when the input signal SIG_{IN1} is at the first operation voltage VDD, and the control signal SIG_{C1} would be at the first operation voltage VDD when the input signal SIG_{IN1} is at the system voltage VSS. Similarly, the control signal SIG_{C2} would be at the boost voltage VBST when the input signal SIG_{IN2} is at the first operation voltage VDD, and the control signal SIG_{C2} would be at the first operation voltage VDD when the input signal SIG_{IN2} is at the system voltage VSS. In other words, the control signal SIG_{C1} can be positively correlated to the input signal SIG_{IN1}, and the control signal SIG_{C2} can be positively correlated to the input signal SIG_{IN2.}

In such case, the control terminal of the transistor M1B can receive the control signal SIG_{C1}, and the control terminal of the transistor M2B can receive the control signal SIG_{C2}. In the present embodiment, the boost voltage VBST can be higher than the threshold voltages of the transistors M1B and M2B. Therefore, when the input signal SIG_{IN1} is changed from the system voltage VSS to the first operation voltage VDD, the transistor M1B can be turned on effectively by the control signal SIG_{C1}, which is raised to the boost voltage VBST. Likewise, when the input signal SIG_{IN2} is changed from the system voltage VSS to the first operation voltage VDD, the transistor M2B can be turned on effectively by the control signal SIG_{C2}.

In the present embodiment, the voltage boost unit 220 and the voltage boost unit 230 may have the same structures. For example, the voltage boost unit 220 includes a capacitor C1, a transistor M3B, and an initial voltage booster 222. Also, the voltage boost unit 230 includes a capacitor C1′, a transistor M3B′, and an initial voltage booster 232. As shown in FIG. 2, the capacitor C1 includes a first terminal for receiving the input signal SIG_{IN1}, and a second terminal configured to output the control signal SIG_{C1}. The transistor M3B includes a first terminal coupled to the first operation voltage VDD, a second terminal coupled to the second terminal of the capacitor C1, and a control terminal for receiving the control signal SIG_{C2}. The initial voltage booster 222 includes a transistor M4B. The transistor M4B includes a first terminal coupled to the first operation voltage VDD, a second terminal coupled to the second terminal of the capacitor C1, and a control terminal coupled to the first terminal of the transistor M4B.

In the present embodiment, the input signal SIG_{IN1} is kept at the system voltage VSS and the second input signal SIG_{IN2} is kept at the first operation voltage VDD, before the falling edge of the enable signal SIG_{EN} at the time T1, and the input signals SIG_{IN1} and SIG_{IN2} may start to change according to the required operation to be performed after the time T1. In such case, before any of the input signal SIG_{IN1} or SIG_{IN2} is changed to the first operation voltage VDD for the first time, the initial voltage boosters 222 and 232 can raise voltages of the control signals SIG_{C1} and SIG_{C2} to a certain level, thereby ensuring the voltage boost units 220 and 230 can boost the input signals SIG_{IN1} and SIG_{C2} to the desired levels in the later stage.

For example, before time T2, if the control signal SIG_{C1} is at a voltage lower than the first operation voltage VDD minus a threshold voltage Vt of the transistor M4B, then the transistor M4B will be turned on, and the capacitor C1 can be charged, thereby raising the control signal SIG_{C1} to a voltage equal to the first operation voltage VDD minus the threshold voltage Vt. In such case, the initial voltage booster 222 can charge the capacitor C1 so as to raise a voltage of the control signal SIG_{C1} to an initial voltage level (i.e. the first operation voltage VDD minus the threshold voltage Vt of the transistor M4B) before the first control signal SIG_{C2} is raised for the first time. Similarly, before time T2, the control signal SIG_{C2} is also raised to the voltage equal to the first operation voltage VDD minus a threshold voltage Vt due to the initial voltage booster 232.

In such case, when the input signal SIG_{IN1} is changed to the first operation voltage VDD at the time T2, the voltage of the control signal SIG_{C1} can be coupled to a voltage equal to two times the first operation voltage VDD minus the threshold voltage Vt (i.e., 2VDD−Vt) due to the capacitor C1. As the control signal SIG_{C1} is raised to (2VDD−Vt), it becomes higher than the first operation voltage VDD and the threshold voltage of the transistor M1B. Therefore, the transistor M1B can be turned on accordingly by the control signal SIG_{C1}, thereby pulling down the voltage of the first terminal of the latch 110. As a result, the output signal SIG_{OUT} would be pulled up to the second operation voltage VDD2 at time T2 as desired.

In addition, since the control signal SIG_{C1} is raised to be higher than the first operation voltage VDD, the transistor M3B′ in the voltage boost unit 230 can be fully turned on, so the voltage of the control signal SIG_{C2} is raised to the first operation voltage VDD. Subsequently, when the input signal SIG_{IN1} is changed to the system voltage VSS and the input signal SIG_{IN2} is changed to the first operation voltage VDD at time T3, the control signal SIG_{C2} would be coupled to the boost voltage VBST (which is equal to two times the first operation voltage VDD) through the capacitor C1′. As a result, the transistor M2B can be turned on accordingly, thereby pulling down the output signal SIG_{OUT} at the time T3.

Furthermore, since the control signal SIG_{C2} is raised to the boost voltage VBST that is higher than the first operation voltage VDD, the transistor M3B in the voltage boost unit 220 can be fully tuned on, thereby setting the control signal SIG_{C1} to the first operation voltage VDD. In such case, next time when the input signal SIG_{IN1} is changed from the system voltage VSS to the first operation voltage VDD at time T4, the control signal SIG_{C1} would be coupled to the boost voltage VBST. Therefore, after time T3, the control signals SIG_{C1} and SIG_{C2} can be switched between the boost voltage VBST and the first operation voltage VDD as the input signals SIG_{IN1} and SIG_{IN2} are switched between the first operation voltage VDD and the system voltage VSS.

In the present embodiment, as shown in FIG. 2, the voltage boost unit 220 further includes a well selector 224, and the voltage boost unit 230 further includes a well selector 234. The well selector 224 is coupled to body terminals of the transistors M3B and M4B, and can set voltages of the body terminals of the transistors M3B and M4B to a lower one between the first operation voltage VDD and a voltage of the control signal SIG_{C1}.

For example, the well selector 224 may include transistors M5B and M6B. The transistor M5B includes a first terminal coupled to the first operation voltage VDD, a second terminal coupled to the body terminals of the transistors M3B and M4B, and a control terminal coupled to the second terminal of the capacitor C1. The transistor M6B includes a first terminal coupled to the second terminal of the transistor M5B, a second terminal coupled to the second terminal of the capacitor C1, and a control terminal coupled to the first operation voltage VDD. As a result, the body terminal of the transistor M3B can be set to the lower one between the first operation voltage VDD and a voltage of the control signal SIG_{C1}, thereby avoiding the body effect and current leakage caused by forward biasing of the body-source junction. In some embodiments, the body terminals of the transistors M5B and M6B are also coupled to the second terminal of the transistor M5B so as to prevent the body effect and current leakage. In some embodiments that the well selector 224 is omitted, the body terminals of the transistors M3B and M4B are coupled to the first operation voltage VDD.

In addition, in some embodiments, since the cross voltages applied to the transistors in the voltage boost units 220 and 230 are no greater than the first operation voltage VDD, such transistors can be low voltage transistors that have thinner gate oxide than the transistors M1B and M2B, which are medium voltage transistors or high voltage transistors. In such case, the threshold voltages of the transistors in the initial voltage boosters 222, 232 and the well selectors 224 and 234 (including transistors M3B, M3B′, M4B, M5B, and M6B) would be smaller than the threshold voltages of the transistors M1B and M2B.

In the present embodiment, the level shift circuit 200 further includes a transistor M7B. The transistor M7B includes a first terminal coupled to the second terminal of the latch 110, a second terminal coupled to the system voltage VSS, and a control terminal for receiving the enable signal SIG_{EN}. The transistor M7B can help to ensure the latch 110 to be in a stable condition before the enable signal SIG_{EN} falls to the system voltage VSS. For example, as shown in FIG. 3, before time T1, the enable signal SIG_{EN} is at the second operation voltage VDD2, thereby turning on the transistor M7B and setting the voltage of the second terminal of the latch 110 at the system voltage VSS. Also, when the system is ready after time T1, the enable signal SIG_{EN} is set to the system voltage VSS, and the transistor M7B is turned off, thereby allowing the level shift circuit 200 to control the output signal SIG_{OUT} according to the input signals SIG_{IN1} and SIG_{IN2}. In other words, the transistor M7B can be turned off before the first control signal SIG_{C1} is raised for the first time at time T2.

In some embodiments, the first operation voltage VDD may be higher than the threshold voltages of the transistors M1B and M2B under some operation condition, making it difficult to turn off the transistors M1B and M2B. To solve this issue, the structure of cascode transistors can be adopted.

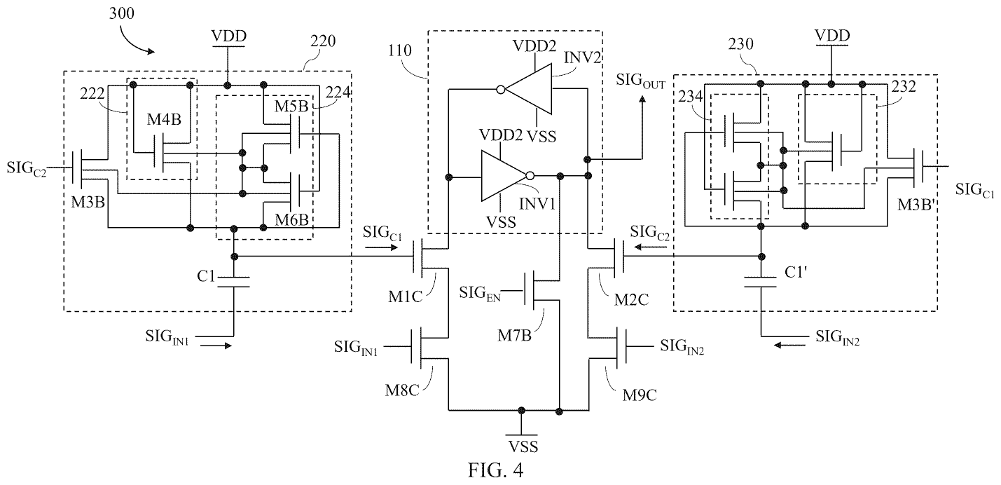

FIG. 4 shows a level shift circuit 300 according to another embodiment of the present disclosure. The level shift circuit 300 is different from the level shift circuit 200 in that the level shift circuit 300 further includes a transistor M8C in a cascode configuration with the transistor M1C, and a transistor M9C in a cascode configuration with the transistor M2C. Specifically, the transistor M8C includes a first terminal coupled to the second terminal of the transistor M1C, a second terminal coupled to the system voltage VSS, and a control terminal for receiving the input signal SIG_{IN1}. The transistor M9C includes a first terminal coupled to the second terminal of the transistor M2C, a second terminal coupled to the system voltage VSS, and a control terminal for receiving the input signal SIG_{IN2}.

In the present embodiment, the transistors M8C and M9C are low voltage transistors, and the threshold voltages of the transistors M8C and M9C are both lower than the first operation voltage VDD and higher than the system voltage VSS. Therefore, even if the transistors M1C and M2C cannot be turned off when the control signals SIG_{C1} and SIG_{C2} are at the first operation voltage VDD, the transistors M8C and M9C can still be turned off by the input signals SIG_{IN1} and SIG_{IN2} when the input signals SIG_{IN1} and SIG_{IN2} are at the system voltage VSS.

In the present embodiment, the input signals SIG_{IN1} and SIG_{IN2} are respectively kept at the system voltage VSS and the first operation voltage VDD before the falling edge of the enable signal SIG_{EN} of the level shift circuit 200 or 300, so that the latch 110 can remain stable before the transistor M7B is turned off, thereby reducing the current leakage through the transistor M7B. However, in some embodiments, according to the design, the system may not force the input signal SIG_{IN1} and SIG_{IN2} respectively at the system voltage VSS and the first operation voltage VDD before the falling edge of the enable signal SIG_{EN}, that is, the input signal SIG_{IN1} and SIG_{IN2} may start to change even before the falling edge of the enable signal SIG_{EN} of the level shift circuit 200 or 300. In such case, additional pulse signals for controlling the transistors M8C and M9C to reduce the current leakage may be generated according to the input signals SIG_{IN1} and SIG_{IN2}.

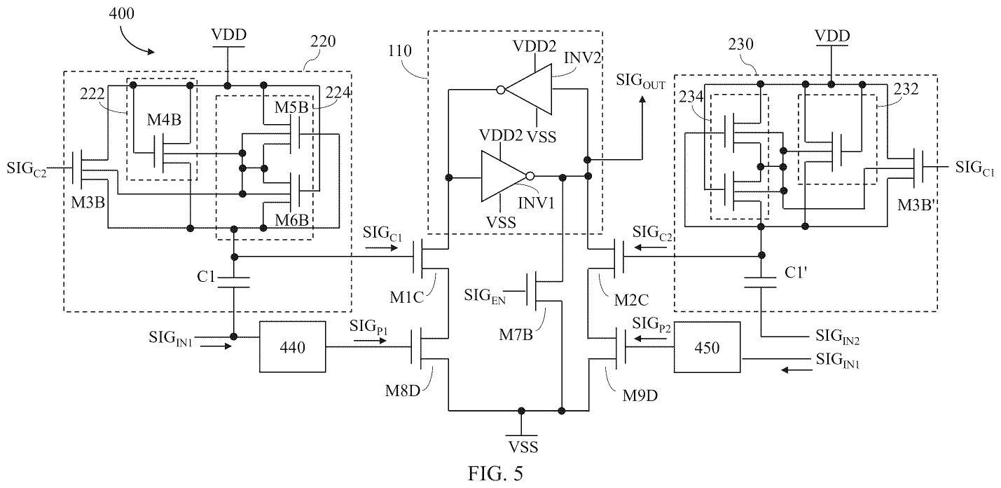

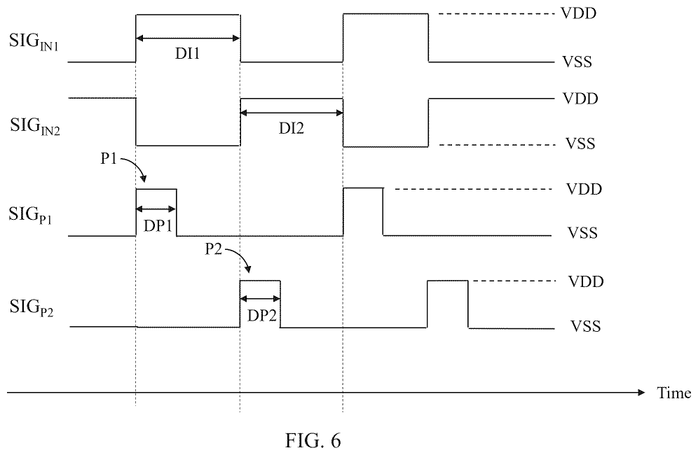

FIG. 5 shows a level shift circuit 400 according to one embodiment of the present disclosure. The level shift circuit 400 is different from the level shift circuit 300 in that control terminals of the transistors M8D and M9D may receive the pulse signals SIG_{P1} and SIG_{P2} rather than the input signals SIG_{IN1} and SIG_{IN2}. FIG. 6 shows a timing diagram of the input signals SIG_{IN1} and SIG_{IN2} and the pulse signals SIG_{P1} and SIG_{P2.}

As shown in FIG. 6, in response to the input signal SIG_{IN1} changing from the system voltage VSS to the first operation voltage VDD, a pulse of the pulse signal SIG_{P1} is generated, and in response to the input signal SIG_{IN2} changing from the system voltage VSS to the first operation voltage VDD, a pulse of the pulse signal SIG_{P2} is generated. In the present embodiment, the duration DP1 and DP2 of the pulses P1 and P2 of the pulse signals SIG_{P1} and SIG_{P2} can be shorter than the durations DI1 and DI2 of the input signals SIG_{IN1} and SIG_{IN2} at the first operation voltage VDD, therefore, the current leakage can be reduced.

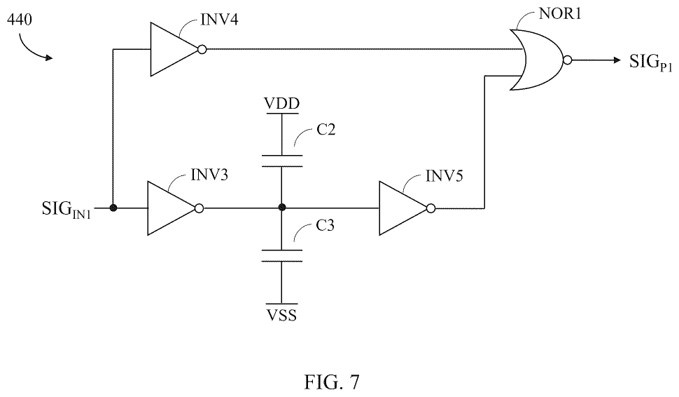

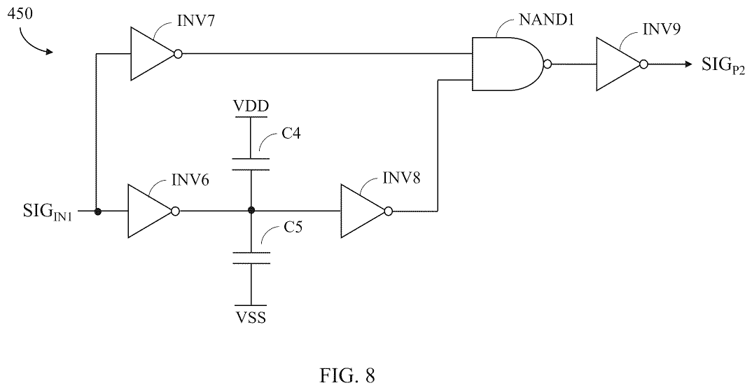

In the present embodiment, the level shift circuit 400 may further include pulse generators 440 and 450 for generating the pulse signals SIG_{P1} and SIG_{P2} respectively. FIG. 7 shows the pulse generator 440 according to one embodiment of the present disclosure and FIG. 8 shows the pulse generator 450 according to one embodiment of the present disclosure.

As shown in FIG. 7, the pulse generator 440 includes inverters INV3, INV4, and INV5, capacitors C2 and C3, and a NOR gate NOR1. The inverter INV3 includes an input terminal for receiving the input signal SIG_{IN1}, and an output terminal. The capacitor C2 includes a first terminal coupled to the first operation voltage VDD, and a second terminal coupled to the output terminal of the third inverter INV3. The capacitor C3 includes a first terminal coupled to the output terminal of the inverter INV3, and a second terminal coupled to the system voltage VSS. The inverter INV4 includes an input terminal for receiving the input signal SIG_{IN1}, and an output terminal. The inverter INV5 includes an input terminal coupled to the output terminal of the inverter INV3, and an output terminal. The NOR gate NOR1 includes a first input terminal coupled to the output terminal of the inverter INV4, a second input terminal coupled to the output terminal of the inverter INV5, and an output terminal for outputting the pulse signal SIG_{P1}.

As shown in FIG. 8, the pulse generator 450 includes inverters INV6, INV7, INV8, and INV9, capacitors C4 and C5, and a NAND gate NAND1. The inverter INV6 includes an input terminal for receiving the input signal SIG_{IN1}, and an output terminal. The capacitor C4 includes a first terminal coupled to the first operation voltage VDD, and a second terminal coupled to the output terminal of the inverter INV6. The capacitor C5 includes a first terminal coupled to the output terminal of the sixth inverter INV6, and a second terminal coupled to the system voltage VSS. The inverter INV7 includes an input terminal for receiving the input signal SIG_{IN1}, and an output terminal. The inverter INV8 includes an input terminal coupled to the output terminal of the inverter INV6, and an output terminal. The NAND gate NAND1 includes a first input terminal coupled to the output terminal of the inverter INV7, a second input terminal coupled to the output terminal of the inverter INV8, and an output terminal. The ninth inverter INV9 includes an input terminal coupled to the output terminal of the NAND gate NAND1, and an output terminal for outputting the pulse signal SIG_{P2.}

It should be noticed that, the structures of the pulse generators 440 and 450 shown in FIG. 7 and FIG. 8 are for exemplary purpose but not to limit the present disclosure. In some embodiments, other structures may be adopted to generate the pulse signals SIG_{P1} and SIG_{P2} according to the input signal SIG_{IN1} or SIG_{IN2}.

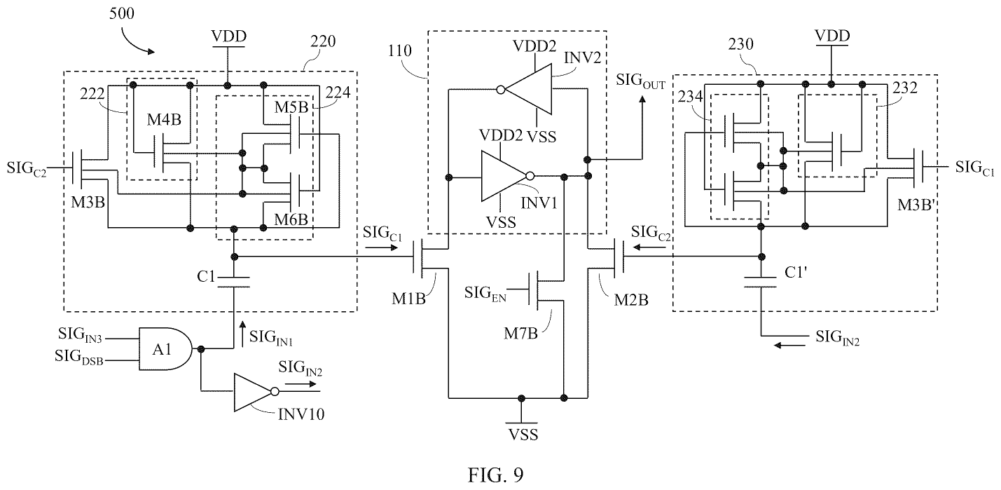

FIG. 9 shows a level shift circuit 500 according to one embodiment of the present disclosure. The level shift circuit 500 is different from the level shift circuit 200 in that the level shift circuit 500 further includes an AND gate A1 and an inverter INV10 for generating the input signals SIG_{IN1} and SIG_{IN2} according to an input signal SIG_{IN3} and an disable signal SIG_{DSB}. In the level shift circuit 200 shown in FIG. 2, the input signal SIG_{IN1} and SIG_{IN2} can be designed to stay at the system voltage VSS before the enable signal SIG_{EN} changes from the second operation voltage VDD2 to the system voltage VSS so as to prevent the current leakage on the transistors M1B and M2B. However, in some embodiments, the input signal SIG_{IN1} may be changed to the first operation voltage VDD before the enable signal SIG_{EN} changes from the second operation voltage VDD2 to the system voltage VSS, and thus, the current leakage may be caused. As shown in FIG. 9, to prevent such current leakage, the input signal SIG_{IN1} can be generated by combining the input signal SIG_{IN3} with the disable signal SIG_{DSB} using the logical AND gate A1 so as to ensure that the control terminals of the transistors M1B and M2B can receive the system voltage VSS before the enable signal SIG_{EN} changes from the second operation voltage VDD2 to the system voltage VSS.

Specifically, the AND gate A1 includes a first input terminal for receiving the input signal SIG_{IN3}, a second input terminal for receiving the disable signal SIG_{DSB}, and an output terminal for outputting the input signal SIG_{IN1}. The inverter INV10 includes an input terminal for receiving the input signal SIG_{IN1}, and an output terminal for outputting the input signal SIG_{IN2.}

In the present embodiment, the disable signal SIG_{DSB} is complementary with the enable signal SIG_{EN}, however, the enable signal SIG_{EN} is in the voltage domain of the second operation voltage VDD2 while the disable signal SIG_{DSB} is in the voltage domain of the first operation voltage VDD. In other words, when the enable signal SIG_{EN} is at the second operation voltage VDD2, the disable signal SIG_{DSB} is at the system voltage VSS, and when the enable signal SIG_{EN} is at the system voltage VSS, the disable signal SIG_{DSB} is at the first operation voltage VDD. In such case, when the enable signal SIG_{EN} is at the second operation voltage VDD2, the input signal SIG_{IN1} would stay at the system voltage VSS even if the input signal SIG_{IN3} is changed to the first operation voltage VDD, so that before the enable signal SIG_{EN} falls to the system voltage VSS, both the transistors M1B and M2B can be turned off, thereby reducing the current leakage.

In summary, the level shift circuit provided by the embodiments of the present disclosure can include voltage boost units for boosting the input voltages for controlling the latch, thereby ensuring the functionality of the level shift circuit.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A level shift circuit comprising:
a first voltage boost unit configured to generate a first control signal according to a first input signal switched between a first operation voltage and a system voltage lower than the first operation voltage, wherein the first control signal is positively correlated to the first input signal and is at a boost voltage higher than the first operation voltage when the first input signal is at the first operation voltage;
a second voltage boost unit configured to generate a second control signal according to a second input signal switched between the first operation voltage and the system voltage and complementary to the first input signal, wherein the second control signal is positively correlated to the second input signal and is at the boost voltage when the second input signal is at the first operation voltage;
a latch comprising a first terminal and a second terminal, and configured to latch a voltage of one of the first terminal and the second terminal of the latch at a second operation voltage higher than the first operation voltage and latch a voltage of another of the first terminal and the second terminal of the latch at the system voltage;
a first transistor comprising a first terminal coupled to the first terminal of the latch, a second terminal, and a control terminal configured to receive the first control signal; and
a second transistor comprising a first terminal coupled to the second terminal of the latch, a second terminal, and a control terminal configured to receive the second control signal.

2. The level shift circuit of claim 1, wherein the first control signal is at the first operation voltage when the first input signal is at the system voltage, and the second control signal is at the first operation voltage when the second input signal is at the system voltage.

3. The level shift circuit of claim 1, wherein the first voltage boost unit comprises:
a first capacitor comprising a first terminal configured to receive the first input signal, and a second terminal configured to output the first control signal;
a third transistor comprising a first terminal coupled to the first operation voltage, a second terminal coupled to the second terminal of the first capacitor, and a control terminal configured to receive the second control signal; and
an initial voltage booster configured to charge the first capacitor so as to raise a voltage of the first control signal to an initial voltage level before the first control signal is raised for a first time.

4. The level shift circuit of claim 3, wherein the initial voltage booster comprises:
a fourth transistor comprising a first terminal coupled to the first operation voltage, a second terminal coupled to the second terminal of the first capacitor, and a control terminal coupled to the first terminal of the fourth transistor; and
wherein the initial voltage level is equal to the first operation voltage minus a threshold voltage of the fourth transistor.

5. The level shift circuit of claim 4, wherein a threshold voltage of the third transistor and the threshold voltage of the fourth transistor are lower than a threshold voltage of the first transistor.

6. The level shift circuit of claim 4, wherein the first voltage boost unit further comprises a well selector coupled to body terminal s of the third transistor and the fourth transistor, and configured to set voltages of the body terminal s of the third transistor and the fourth transistor to a lower one between the first operation voltage and a voltage of the first control signal.

7. The level shift circuit of claim 6, wherein the well selector comprises:
a fifth transistor comprising a first terminal coupled to the first operation voltage, a second terminal coupled to the body terminals of the third transistor and the fourth transistor, and a control terminal coupled to the second terminal of the first capacitor; and
a sixth transistor comprising a first terminal coupled to the second terminal of the fifth transistor, a second terminal coupled to the second terminal of the first capacitor, and a control terminal coupled to the first operation voltage.

8. The level shift circuit of claim 7, wherein a threshold voltage of the fifth transistor and a threshold voltage of the sixth transistor are both lower than a threshold voltage of the first transistor.

9. The level shift circuit of claim 1, wherein the latch comprises:
a first inverter comprising an input terminal coupled to the first terminal of the latch, and an output terminal coupled to the second terminal of the latch; and
a second inverter comprising an input terminal coupled to the second terminal of the latch, and an output terminal coupled to the first terminal of the latch.

10. The level shift circuit of claim 1, further comprising a seventh transistor comprising a first terminal coupled to the second terminal of the latch, a second terminal coupled to the system voltage, and a control terminal configured to receive an enable signal, wherein the seventh transistor is turned off before the first control signal is raised for a first time.

11. The level shift circuit of claim 10, wherein the first input signal is at the system voltage and the second input signal is at the first operation voltage before the seventh transistor is turned off.

12. The level shift circuit of claim 1, further comprising:
an eighth transistor comprising a first terminal coupled to the second terminal of the first transistor, a second terminal coupled to the system voltage, and a control terminal configured to receive the first input signal; and
a ninth transistor comprising a first terminal coupled to the second terminal of the second transistor, a second terminal coupled to the system voltage, and a control terminal configured to receive the second input signal.

13. The level shift circuit of claim 12, wherein a threshold voltage of the eighth transistor and a threshold voltage of the ninth transistor are both lower than the first operation voltage and higher than the system voltage.

14. The level shift circuit of claim 1, further comprising:
an eighth transistor comprising a first terminal coupled to the second terminal of the first transistor, a second terminal coupled to the system voltage, and a control terminal configured to receive a first pulse signal; and
a ninth transistor comprising a first terminal coupled to the second terminal of the second transistor, a second terminal coupled to the system voltage, and a control terminal configured to receive a second pulse signal;
wherein a pulse of the first pulse signal is generated in response to the first input signal changing from the system voltage to the first operation voltage, and a pulse of the second pulse signal is generated in response to the second input signal changing from the system voltage to the first operation voltage.

15. The level shift circuit of claim 14, further comprising a first pulse generator configured to generate the first pulse signal, wherein the first pulse generator comprises:
a third inverter comprising an input terminal configured to receive the first input signal, and an output terminal;
a second capacitor comprising a first terminal coupled to the first operation voltage, and a second terminal coupled to the output terminal of the third inverter;
a third capacitor comprising a first terminal coupled to the output terminal of the third inverter, and a second terminal coupled to the system voltage;
a fourth inverter comprising an input terminal configured to receive the first input signal, and an output terminal;
a fifth inverter comprising an input terminal coupled to the output terminal of the third inverter, and an output terminal;
a NOR gate comprising a first input terminal coupled to the output terminal of the fourth inverter, a second input terminal coupled to the output terminal of the fifth inverter, and an output terminal configured to output the first pulse signal.

16. The level shift circuit of claim 14, further comprising a second pulse generator configured to generate the second pulse signal, wherein the second pulse generator comprises:
a sixth inverter comprising an input terminal configured to receive the first input signal, and an output terminal;
a fourth capacitor comprising a first terminal coupled to the first operation voltage, and a second terminal coupled to the output terminal of the sixth inverter;
a fifth capacitor comprising a first terminal coupled to the output terminal of the sixth inverter, and a second terminal coupled to the system voltage;
a seventh inverter comprising an input terminal configured to receive the first input signal, and an output terminal;
an eighth inverter comprising an input terminal coupled to the output terminal of the sixth inverter, and an output terminal;
a NAND gate comprising a first input terminal coupled to the output terminal of the seventh inverter, a second input terminal coupled to the output terminal of the eighth inverter, and an output terminal; and
a ninth inverter comprising an input terminal coupled to the output terminal of the NAND gate, and an output terminal configured to output the second pulse signal.

17. The level shift circuit of claim 1, further comprising:
an AND gate comprising a first input terminal configured to receive a third input signal, a second input terminal configured to receive a disable signal, and an output terminal configured to output the first input signal; and
an inverter comprising an input terminal configured to receive the first input signal, and an output terminal configured to output the second input signal.
